(19) United States
(12) Patent Application Publication
(10) Pub. No.: US 2017/0084464 A1
(43) Pub. Date: Mar. 23, 2017

(54) GERMANIUM-CONTAINING SEMICONDUCTOR DEVICE AND METHOD OF FORMING

(71) Applicant: Tokyo Electron Limited, Tokyo (JP)

(72) Inventors: Kandabara N. Tapily, Albany, NY (US); Robert D. Clark, Livermore, CA (US); Steven P. Consiglio, Albany, NY (US); Cory Wajda, Sand Lake, NY (US); Gerrit J. Leusink, Rexford, NY (US)

(21) Appl. No.: 15/267,890

(22) Filed: Sep. 16, 2016

Related U.S. Application Data
(60) Provisional application No. 62/220,784, filed on Sep. 18, 2015.

(51) Int. Cl. H01L 21/28; H01L 21/3105; H01L 29/51; H01L 21/02

(52) U.S. Cl. CPC H01L 21/28255; H01L 21/02178; H01L 21/02181; H01L 21/02189; H01L 21/02186; H01L 21/02192; H01L 21/0234; H01L 21/0228; H01L 21/31051; H01L 29/517

(57) ABSTRACT

A germanium-containing semiconductor device and a method for forming a germanium-containing semiconductor device are described. The method includes providing a germanium-containing substrate, depositing an aluminum-containing diffusion barrier layer on the germanium-containing substrate, depositing a high-k layer on the aluminum-containing diffusion barrier layer, and exposing the high-k layer to atomic oxygen to reduce the equivalent oxide thickness (EOT) of the high-k layer while avoiding oxidizing the germanium-containing substrate. The germanium-containing semiconductor device includes a germanium-containing substrate, an aluminum-containing diffusion barrier layer on the germanium-containing substrate, and a high-k layer on the aluminum-containing diffusion barrier layer, where the high-k layer has been exposed to atomic oxygen to reduce the EOT of the high-k layer while avoiding oxidizing the germanium-containing substrate.

### FIELD OF THE INVENTION

The present invention generally relates to a semiconductor device, and more particularly to a germanium-containing semiconductor device containing a low equivalent oxide thickness (EOT) high-k layer on the germanium-containing substrate and a method of forming the device.

### BACKGROUND OF THE INVENTION

As metal-oxide-semiconductor field-effect transistors (MOSFETs) continue to scale, a short channel effect has become an increasing problem and new device architectures such as FinFETs and trigates have been introduced. Semiconductor devices with a high-mobility channel, such as germanium(Ge)-containing semiconductor devices and III-V semiconductor devices, offer the possibility of increased device performance beyond traditional silicon(Si)-containing semiconductor devices. A challenge for germanium-containing semiconductor devices containing a high dielectric constant (high-k) layer includes the need to protect the germanium-containing substrate against oxidation and/or degradation during deposition and processing of the high-k layer on the germanium-containing substrate.

### SUMMARY OF THE INVENTION

A germanium-containing semiconductor device and a method for forming a germanium-containing semiconductor device are described. The germanium-containing semiconductor device includes a germanium-containing substrate, an aluminum-containing diffusion barrier layer on the germanium-containing substrate, and a high-k layer on the aluminum-containing diffusion barrier layer, where the high-k layer has been exposed to atomic oxygen to reduce the equivalent oxide thickness (EOT) of the high-k layer while avoiding oxidizing the germanium-containing substrate.

According to one embodiment, the method includes providing a germanium-containing substrate, depositing an aluminum-containing diffusion barrier layer on the germanium-containing substrate, depositing a high-k layer on the aluminum-containing diffusion barrier layer, and exposing the high-k layer to atomic oxygen to reduce the EOT of the high-k layer while avoiding oxidizing the germanium-containing substrate.

### BRIEF DESCRIPTION OF THE DRAWINGS

In the accompanying drawings:

FIG. 1 shows a process flow diagram for a method of forming a germanium-containing semiconductor device according to an embodiment of the invention;

FIG. 2 shows capacitance versus voltage for germanium-containing test samples;

FIG. 3 shows leakage density versus capacitive effective thickness (CET) for the germanium-containing test samples of FIG. 2;

FIG. 4 is a schematic diagram of a plasma processing system containing a microwave plasma source for processing a substrate according to an embodiment of the invention;

FIG. 5 is a schematic diagram of another plasma processing system containing a microwave plasma source for processing a substrate according to an embodiment of the invention;

FIG. 6 illustrates a plan view of a gas supplying unit of the plasma processing system in FIG. 5; and

FIG. 7 illustrates a partial cross-sectional view of an antenna portion of the plasma processing system in FIG. 5.

### DETAILED DESCRIPTION OF SEVERAL EMBODIMENTS

A challenge for advanced germanium-containing semiconductor devices includes the need to protect a germanium-containing substrate against oxidation and/or degradation during semiconductor processing, for example during deposition and post-deposition processing of a high-k layer on the germanium-containing substrate. Embodiments of the invention describe a method for forming an aluminum-containing diffusion barrier layer between the germanium-containing substrate and the high-k layer. The aluminum-containing diffusion barrier layer (e.g., Al₂O₃) provides a good barrier to germanium diffusion into overlying high-k layer and a good barrier to oxygen diffusion into the germanium-containing substrate during post-deposition processing that includes exposing the high-k layer to atomic oxygen to reduce the equivalent oxide thickness (EOT) of the high-k layer while avoiding oxidizing the germanium-containing substrate.

The inventors have discovered that exposing the high-k layer to atomic oxygen to reduce the equivalent oxide thickness (EOT) of the high-k layer while avoiding oxidizing the germanium-containing substrate results in low EOT (e.g., less than 7 Angstrom (Å)) which achieves the International Technology Roadmap for Semiconductors (ITRS) requirement for leakage current density and thermal stability (<500° C.) for 10 nm, 7 nm, and 5 nm nodes.

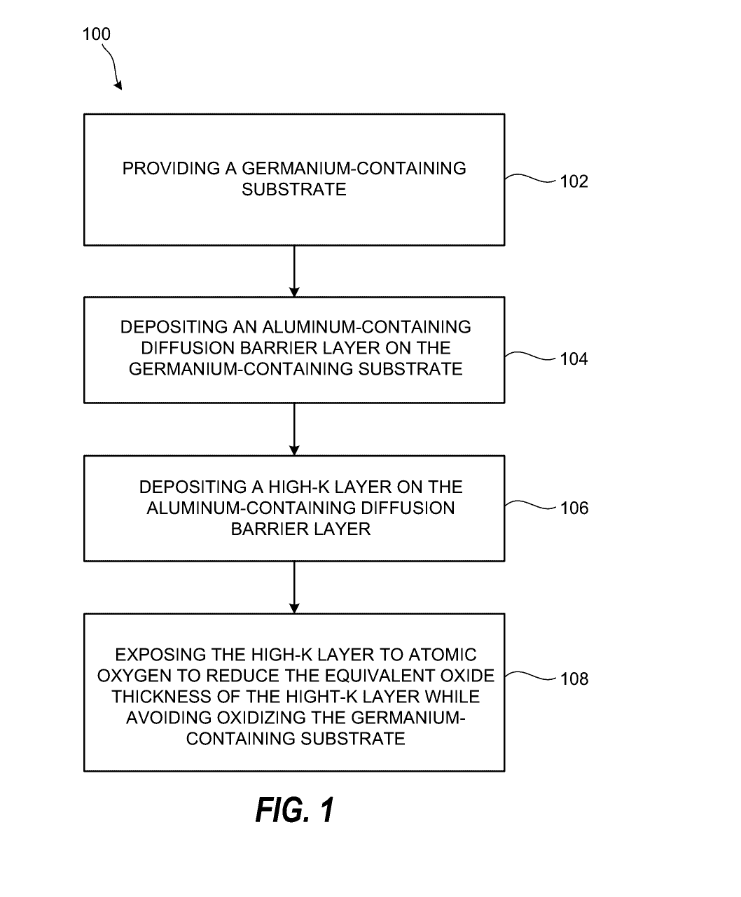

Referring now to the figures, FIG. 1 shows a process flow diagram 100 for a method of forming a germanium-containing semiconductor device according to an embodiment of the invention. In 102, the method includes providing a germanium-containing substrate in a process chamber. In some examples, the process chamber may be capable of performing thin film deposition that can selected from atomic layer deposition (ALD), chemical vapor deposition (CVD), plasma-enhanced ALD (PEALD), and plasma-enhanced CVD (PECVD). The germanium-containing substrate can include Ge or SiGe. The SiGe can be expressed as SiₓGe₁₋ₓ, where x is the atomic fraction of Si and 1-x is the atomic fraction of Ge. Exemplary SiₓGe₁₋ₓ compounds include Si_{0.1}Ge_{0.9}, Si_{0.2}Ge_{0.8}, Si_{0.3}Ge_{0.7}, Si_{0.4}Ge_{0.6}, Si_{0.5}Ge_{0.5}, Si_{0.6}Ge_{0.4}, Si_{0.7}Ge_{0.3}, Si_{0.8}Ge_{0.2}, and Si_{0.9}Ge_{0.1}. The germanium-containing substrate may be cleaned of any oxide layer or contaminants using dilute hydrofluoric acid (DHF) or a chemical oxide removal process (COR). Thus, a surface of the germanium-containing substrate may be prepared to be substantially free of oxygen. Alternatively, a GeO₂ layer may be formed on the germanium-containing substrate. However, the presence of a GeO₂ layer can increase the equivalent oxide thickness (EOT) of the final germanium-containing semiconductor device.

In 104, the method further includes depositing an aluminum-containing diffusion barrier layer on the germanium-containing substrate. A thickness of the aluminum-containing diffusion barrier layer can be, for example, between about 3 Å and about 20 Å, between about 3 Å and about 10 Å, or between about 4 Å and about 6 Å. In one embodiment, the aluminum-containing diffusion barrier layer can contain aluminum oxide (Al₂O₃), aluminum oxynitride (AlON), aluminum nitride (AlN), or a combination thereof. The aluminum-containing diffusion barrier layer may be deposited onto the germanium-containing substrate by ALD, CVD, PEALD, or PECVD, using an aluminum precursor, and an oxidation source, a nitridation source, or both an oxidation source and a nitridation source.

Embodiments of the invention may utilize a wide variety of aluminum precursors for depositing the aluminum-containing diffusion barrier layer. Examples of aluminum precursors include, but are not limited to, AlMe₃, AlEt₃, AlMe₂H, [Al(OsBu)₃]₄, Al(CH₃COCHCOCH₃)₃, AlCl₃, AlBr₃, AlI₃, Al(OiPr)₃, [Al(NMe₂)₃]₂, Al(iBu)₂Cl, Al(iBu)₃, Al(iBu)₂H, AlEt₂Cl, Et₃Al₂(OsBu)₃, Al(THD)₃, H₃AlNMe₃, H₃AlNEt₃, H₃AlNMe₂Et, and H₃AlMeEt₂.

Embodiments of the invention may utilize a wide variety of oxidation sources and nitridation sources for depositing the aluminum-containing diffusion barrier layer. The oxidation sources can include, but are not limited to, O₂, atomic oxygen (O), ozone (O₃), water (H₂O), or peroxide (H₂O₂), or a combination thereof, and optionally an inert gas such as Argon (Ar). The nitridation sources can include, but is not limited to, ammonia (NH₃), atomic nitrogen (N), hydrazine (N₂H₄), and C₁-C₁₀ alkylhydrazine compounds. Common C₁ and C₂ alkylhydrazine compounds include monomethyl-hydrazine (MeNHNH₂), 1,1-dimethyl-hydrazine (Me₂NNH₂), and 1,2-dimethyl-hydrazine (MeNHNHMe). According to one embodiment, a mixture of the oxidation sources and the nitridation sources may be utilized. According to one embodiment, an oxidation and nitridation source may, for example, contain NO, NO₂, or N₂O, or a combination thereof, and optionally an inert gas such as Ar.

In 104, the method further includes depositing a high-k layer on the aluminum-containing diffusion barrier layer. A thickness of the high-k layer can, for example, be between about 1 nm and about 10 nm, between about 1.5 nm and about 5 nm, or between about 2 nm and about 4 nm. The high-k layer may be deposited onto the aluminum-containing diffusion barrier layer by ALD, CVD, PEALD, or PECVD, using a high-precursor, and an oxidation source, a nitridation source, or both an oxidation source and a nitridation source.

In one embodiment, the high-k layer includes hafnium, zirconium, titanium, a rare earth element, or a combination thereof. For example, the high-k layer can contain an oxide of hafnium, an oxide of zirconium, an oxide of titanium, an oxide of a rare earth element, or a combination thereof. Examples include TiO₂, HfO₂, ZrO₂, HfSiO, ZrSiO, HfON, ZrON, HfZrO, HfZrON), HfZrSiO, or HfZrSiON, or a combination of two or more thereof. In other examples, the high-k layer can include an oxide, nitride, or oxynitride containing a rare earth element, such as yttrium (Y), lutetium (Lu), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), or ytterbium (Yb), or any combination of two or more thereof. Examples of a rare earth-based high-k layer 108 include lanthanum oxide (La₂O₃), lutetium oxide (Lu₂O₃), and lanthanum lutetium oxide (LaLuO₃).

Embodiments of the invention may utilize a wide variety of oxidation sources and nitridation sources for depositing the high-k layer. The oxidation sources can include, but is not limited to, O₂, atomic oxygen (O), ozone (O₃), water (H₂O), or peroxide (H₂O₂), or a combination thereof, and optionally an inert gas such as Ar. The nitridation sources can include, but is not limited to, ammonia (NH₃), atomic nitrogen (N), hydrazine (N₂H₄), and C₁-C₁₀ alkylhydrazine compounds. Common C₁ and C₂ alkylhydrazine compounds include monomethyl-hydrazine (MeNHNH₂), 1,1-dimethyl-hydrazine (Me₂NNH₂), and 1,2-dimethyl-hydrazine (MeNHNHMe). According to one embodiment, a mixture of the oxidation sources and the nitridation sources may be utilized. According to one embodiment, an oxidation and nitridation source may, for example, contain NO, NO₂, or N₂O, or a combination thereof, and optionally an inert gas such as Ar.

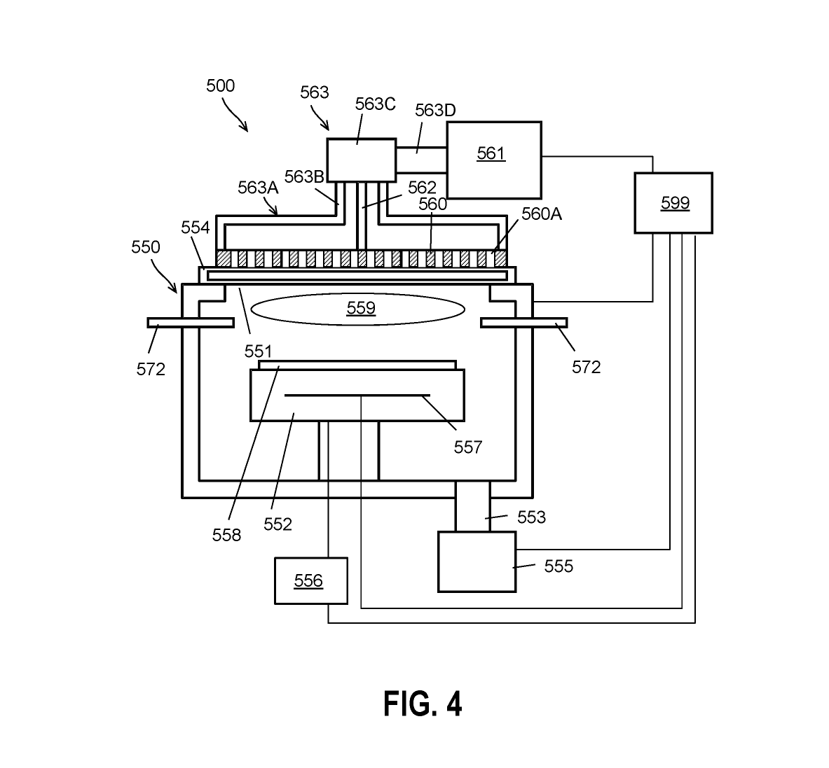

In 108, the method further includes exposing the high-k layer to atomic oxygen to reduce the EOT of the high-k layer while avoiding oxidizing the germanium-containing substrate. According to some embodiments, the exposing includes exposing the high-k layer to plasma-excited oxidizing gas. In one example, the oxidizing gas consists of O₂ and optionally an inert gas. The oxidizing gas may be plasma-excited by a plasma source, for example a microwave plasma source. Examples of microwave plasma sources are described in FIGS. 4-7.

It is contemplated that the exposure of the high-k layer to the atomic oxygen reduces the EOT of the high-k layer by repairing oxygen vacancies in the high-k layer. The presence of the aluminum-containing diffusion barrier layer between the high-k layer and the germanium-containing substrate effectively acts as a barrier to oxygen diffusion during the atomic oxygen exposure, thereby avoiding oxidation of the germanium-containing substrate which would increase the EOT.

The method can further include depositing a metal-containing gate electrode on the high-k layer. In one embodiment, the metal-containing gate electrode can include TiN, TiAlN, W, or TaN, or a combination of two or more thereof. Following deposition of the metal-containing gate electrode on the metal-containing gate electrode, the resulting film structure may be further processed to form a gate stack for a transistor.

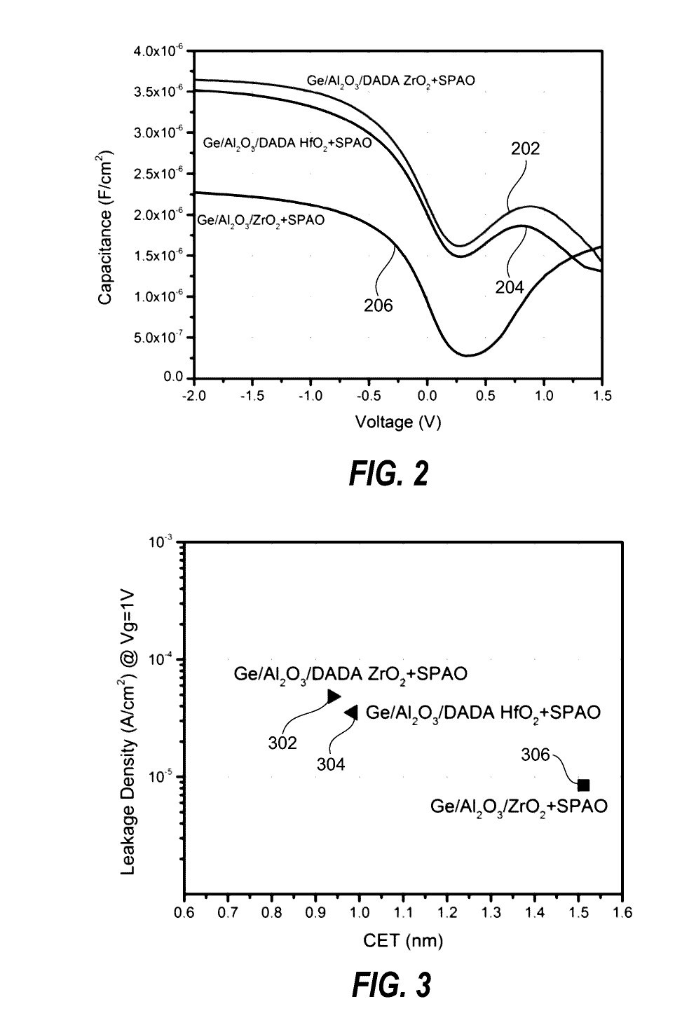

FIG. 2 shows capacitance versus voltage for germanium-containing test samples. The test samples are labeled Ge/Al₂O₃/DADA ZrO₂+SPAO: 202, Ge/Al₂O₃/DADA HfO₂+SPAO: 204, and Ge/Al₂O₃/ZrO₂+SPAO: 206. The HfO₂ and ZrO₂ high-k layers were exposed to a plasma-excited oxidizing gas (O₂+Ar) during a post-deposition treatment (SPAO). The oxidizing gas was plasma-excited using a RLSA™ microwave plasma processing system from Tokyo Electron Limited (Tokyo, Japan). The microwave plasma processing system is well suited for treating the high-k layers due to the low electron temperatures in the plasma. The Al₂O₃ layer was 1 nm thick and was deposited by ALD on the Ge substrate using alternating exposures of trimethylaluminum (TMA) and water (H₂O). The ZrO₂ layer in trace 206 was 3 nm thick and was deposited by ALD on the Al₂O₃ layer using alternating exposures of tetrakisethylmethylamidozirconium (TEMAZ) and H₂O. The ZrO₂ layer in trace 202 was deposited by a modified ALD on the Al₂O₃ layer using alternating exposures of TEMAZ and H₂O with intermittent annealing, denoted by DADA (Deposition, Anneal, Deposition, Anneal). The annealing temperature was set at 800° C. in N₂ ambient. A DADA process is described in U.S. Pat. No. 8,722,548, the entire content of which is hereby incorporated by reference. The HfO₂ layer in trace 204 was 3 nm thick and was deposited by the modified ALD using tetrakisethylmethylamidohafnium (TEMAH) and H₂O with intermittent annealing.

According to one embodiment, the DADA process can include forming at least one first monolayer of first material on a surface of the germanium-containing substrate by performing a first plurality of cycles of atomic layer deposition and, thereafter, annealing the formed at least one first monolayer of first material under a first inert atmosphere at a first temperature, thereafter, forming at least one second monolayer of second material by performing a second plurality of cycles of atomic layer deposition, where the formed at least one second monolayer of second material at least partially overlies the annealed at least one first monolayer of first material, and thereafter, annealing the formed at least one second monolayer of second material under a second inert atmosphere at a second temperature.

FIG. 3 shows leakage density versus capacitive effective thickness (CET) for the germanium-containing test samples of FIG. 2.

CET is related to EOT for ultra-thin gate dielectrics through the equation:

CET˜EOT+(k_{SiO2}/k) Z_{avg}

where k=dielectric constant of the actual material, Z_{avg}=average distance of inversion carriers from the gate-dielectric interface, and k_{SiO2}=dielectric constant of SiO (˜3.9). Further, EOT=(k_{SiO2}/k)t, where t=physical thickness of the actual material.

The CET results in FIG. 3 were calculated from the capacitance versus applied voltage traces of FIG. 2. The CET was ˜0.95 nm (302), ˜1.0 nm (304), and ˜1.5 nm (306) for test samples 202, 204 and 206, respectively. The corresponding EOT values are ˜0.69 nm (302), ˜0.76 nm (304) and ˜1.2 nm (306). For comparison, Ge/Al₂O₃/DADA HfO₂, Ge/Al₂O₃/DADA ZrO₂, and Ge/Al₂O₃/ZrO₂ test samples that were not exposed to a plasma-excited oxidizing gas (O₂+Ar) during a post-deposition treatment (SPAO), had too high leakage density for use in semiconductor devices. This shows that the post-deposition treatment enables the use of these film stacks in semiconductor devices. Further, the film stacks that were deposited by the modified ALD process (DADA), showed improved CET values which allows scaling of these film stacks in narrow nodes, e.g., 10 nm, 7 nm, and 5 nm nodes.

Exemplary microwave plasma processing systems

FIG. 4 is a schematic diagram of a microwave plasma processing system containing a RLSA™ plasma for processing a substrate according to embodiments of the invention. The plasma produced in the plasma processing system 510 is characterized by low electron temperature and high plasma density. The plasma processing system 510 contains a plasma processing chamber 550 having an opening portion 551 in the upper portion of the plasma processing chamber 550 that is larger than a substrate 558. A cylindrical dielectric top plate 554 made of quartz, aluminum nitride, or aluminum oxide is provided to cover the opening portion 551.

Gas lines 572 are located in the side wall of the upper portion of plasma processing chamber 550 below the top plate 554. In one example, the number of gas lines 572 can be 16 (only two of which are shown in FIG. 4). Alternatively, a different number of gas lines 572 can be used. The gas lines 572 can be circumferentially arranged in the plasma processing chamber 550, but this is not required for the invention. A process gas can be evenly and uniformly supplied into the plasma region 559 in plasma processing chamber 550 from the gas lines 572.

In the plasma processing system 510, microwave power is provided to the plasma processing chamber 550 through the top plate 554 via a slot antenna 560 having a plurality of slots 560A. The slot antenna 560 faces the substrate 558 to be processed and the slot antenna 560 can be made from a metal plate, for example copper. In order to supply the microwave power to the slot antenna 560, a waveguide 563 is disposed on the top plate 554, where the waveguide 563 is connected to a microwave power supply 561 for generating microwaves with a frequency of about 2.45 GHz, for example. The waveguide 563 contains a flat circular waveguide 563A with a lower end connected to the slot antenna 560, a circular waveguide 563B connected to the upper surface side of the circular waveguide 563A, and a coaxial waveguide converter 563C connected to the upper surface side of the circular waveguide 563B. Furthermore, a rectangular waveguide 563D is connected to the side surface of the coaxial waveguide converter 563C and the microwave power supply 561.

Inside the circular waveguide 563B, an axial portion 562 of an electroconductive material is coaxially provided, so that one end of the axial portion 562 is connected to the central (or nearly central) portion of the upper surface of slot antenna 560, and the other end of the axial portion 562 is connected to the upper surface of the circular waveguide 563B, thereby forming a coaxial structure. As a result, the circular waveguide 563B is constituted so as to function as a coaxial waveguide. The microwave power can, for example, be between about 0.5 W/cm² and about 4 W/cm². Alternatively, the microwave power can be between about 0.5 W/cm² and about 3 W/cm². The microwave irradiation may contain a microwave frequency of about 300 MHz to about 10 GHz, for example about 2.45 GHz, and the plasma may contain an electron temperature of less than or equal to 5 eV, including 1, 1.5, 2, 2.5, 3, 3.5, 4, 4.5 or 5 eV, or any combination thereof. In other examples, the electron temperature can be below 5 eV, below 4.5 eV, below 4 eV, or even below 3.5 eV. In some examples, the electron temperature can be between 3.0 and 3.5 eV, between 3.5 eV and 4.0 eV, or between 4.0 and 4.5 eV. The plasma may have a density of about 1×10¹¹/cm³ to about 1×10¹³/cm³, or higher.

In addition, in the plasma processing chamber 550, a substrate holder 552 is provided opposite the top plate 554 for supporting and heating a substrate 558 (e.g., a wafer). The substrate holder 552 contains a heater 557 to heat the substrate 525, where the heater 557 can be a resistive heater. Alternatively, the heater 557 may be a lamp heater or any other type of heater. Furthermore the plasma processing chamber 550 contains an exhaust line 553 connected to the bottom portion of the plasma processing chamber 550 and to a vacuum pump 555.

The plasma processing system 510 further contains a substrate bias system 556 configured to bias the substrate holder 552 and the substrate 558 for generating a plasma and/or controlling energy of ions that are drawn to a substrate 558. The substrate bias system 556 includes a substrate power source configured couple power to the substrate holder 552. The substrate power source contains a RF generator and an impedance match network. The substrate power source is configured to couple power to the substrate holder 552 by energizing an electrode in the substrate holder 552. A typical frequency for the RF bias can range from about 0.1 MHz to about 100 MHz, and can be 13.56 MHz. In some examples, the RF bias can be less than 1 MHz, for example less than 0.8 MHz, less than 0.6 MHz, less than 0.4 MHz, or even less than 0.2 MHz. In one example, the RF bias can be about 0.4 MHz. Alternatively, RF power is applied to the electrode at multiple frequencies. The substrate bias system 556 is configured for supplying RF bias power can be between 0 W and 100 W, between 100 W and 200 W, between 200 W and 300 W, between 300 W and 400 W, or between 400 W and 500 W. In some examples, the RF bias power can be less than 100 W, less than 50 W, or less than 25 W, for example. RF bias systems for plasma processing are well known to those skilled in the art. Further, the substrate bias system 556 includes a DC voltage generator capable of supplying DC bias between −5 kV and +5 kV to the substrate holder 552.

The substrate bias system 556 is further configured to optionally provide pulsing of the RF bias power. The pulsing frequency can be greater than 1 Hz, for example 2 Hz, 4 Hz, 6 Hz, 8 Hz, 10 Hz, 20 Hz, 30 Hz, 50 Hz, or greater. It is noted that one skilled in the art will appreciate that the power levels of the substrate bias system 556 are related to the size of the substrate being processed. For example, a 300 mm Si wafer requires greater power consumption than a 200 mm wafer during processing.

Still referring to FIG. 4, a controller 599 is configured for controlling the plasma processing system 510. The controller 599 can include a microprocessor, a memory, and a digital I/O port capable of generating control voltages sufficient to communicate and activate inputs of the plasma processing system 510 as well as monitor outputs from the plasma processing system 510. Moreover, the controller 599 is coupled to and exchanges information with plasma processing chamber 550, the vacuum pump 555, the heater 557, the substrate bias system 556, and the microwave power supply 561. A program stored in the memory is utilized to control the aforementioned components of plasma processing system 510 according to a stored process recipe. One example of controller 599 is a UNIX-based workstation. Alternatively, the controller 599 can be implemented as a general-purpose computer, digital signal processing system, etc.

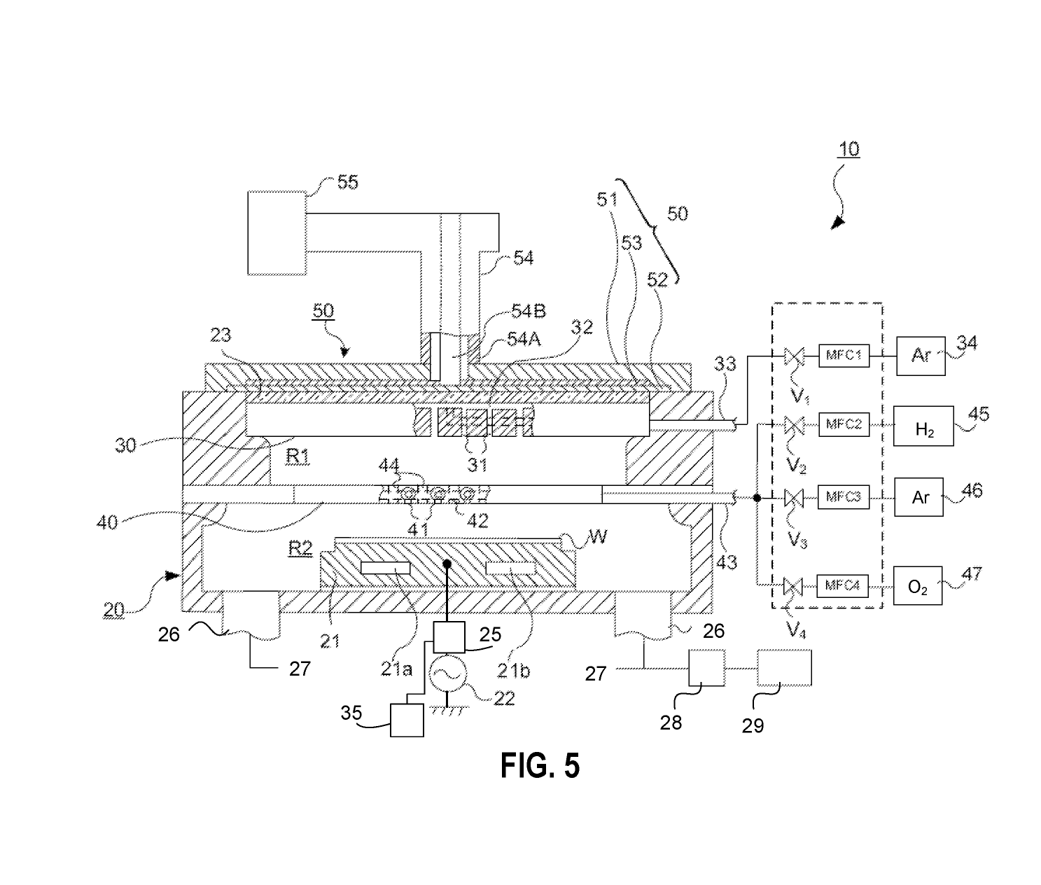

FIG. 5 is a schematic diagram of a microwave plasma processing system containing a RLSA™ plasma for processing a substrate according to another embodiment of the invention. As shown in FIG. 5, the plasma processing system 10 includes a plasma processing chamber 20 (vacuum chamber), an antenna unit 50, and a substrate holder 21. Inside of the plasma processing chamber 20 is roughly sectionalized into a plasma generation region R1, located below a plasma gas supply unit 30, and a plasma diffusion region R2 above the substrate holder 21. A plasma generated in the plasma generation region R1 can have an electron temperature of several electron volts (eV). When the plasma is diffused into the plasma diffusion region R2, where the film formation process is performed, the electron temperature of the plasma near the substrate holder 21 may drop to a value of lower than about 2 eV. The substrate holder 21 is located centrally on a bottom portion of the plasma processing chamber 20 and serves as a substrate holder for supporting a substrate W. Inside the substrate holder 21, there is provided an insulating member 21a, a cooling jacket 21b, and a temperature control unit (not shown) for controlling the substrate temperature.

A top portion of the plasma processing chamber 20 is open-ended. The plasma gas supply unit 30 is placed opposite to the substrate holder 21 and is attached to the top portion of the plasma processing chamber 20 via sealing members such as O rings (not shown). The plasma gas supply unit 30, which may also function as a dielectric window, can be made of materials such as aluminum oxide or quartz and has a planar surface. A plurality of gas supply holes 31 are provided opposite the substrate holder 21 on a planar surface of the plasma gas supply unit 30. The plurality of gas supply holes 31 communicate with a plasma gas supply port 33 via a gas flow channel 32. A plasma gas supply source 34 provides a plasma gas, for example argon (Ar) gas, or other inert gases, into the plasma gas supply port 33. The plasma gas is then uniformly supplied into the plasma generation region R1 via the plurality of gas supply holes 31.

The plasma processing system 10 further includes a process gas supply unit 40, which is centered in the plasma processing chamber 20 between the plasma generation region R1 and the plasma diffusion region R2. The process gas supply unit 40 may be made of a conducting material, for example an aluminum alloy that includes magnesium (Mg), or stainless steel. Similar to the plasma gas supply unit 30, a plurality of gas supply holes 41 are provided on a planar surface of the process gas supply unit 40. The planar surface of the process gas supply unit 40 is positioned opposite to the substrate holder 21.

The plasma processing chamber 20 further includes exhaust lines 26 connected to the bottom portion of the plasma processing chamber 20, a vacuum line 27 connecting the exhaust lines 26 to a pressure controller valve 28 and to a vacuum pump 29. The pressure controller valve 28 may be used to achieve a desired gas pressure in the plasma processing chamber 20.

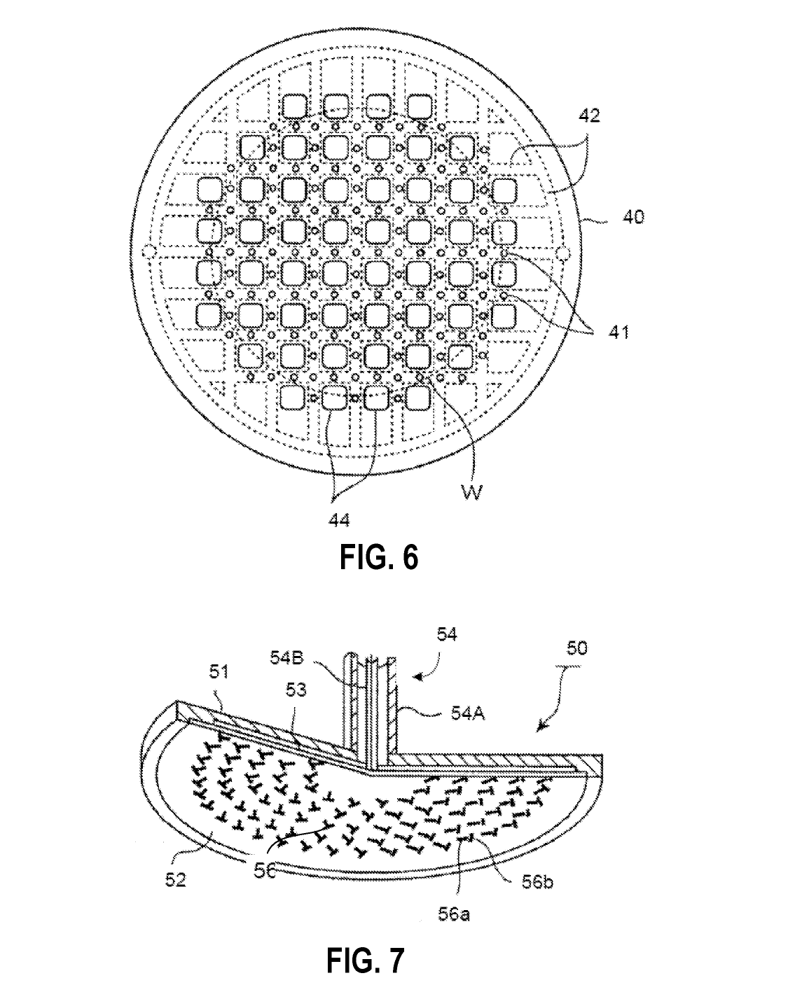

A plan view of the process gas supply unit 40 is shown in FIG. 6. As shown in this figure, grid-like gas flow channels 42 are formed within the process gas supply unit 40. The grid-like gas flow channels 42 communicate with an upper-end of the plurality of gas supply holes 41, which are formed in the vertical direction. The lower portion of the plurality of gas supply holes 41 are openings facing the substrate holder 21. The plurality of gas supply holes 41 communicate with a process gas supply port 43 via the grid-patterned gas flow channels 42.

Further, a plurality of openings 44 are formed in the process gas supply unit 40 such that the plurality of openings 44 pass through the process gas supply unit 40 in the vertical direction. The plurality of openings 44 introduce the plasma gas, e.g., argon (Ar) gas, helium (He) gas, or other inert gases, into the plasma diffusion region R2 above the substrate holder 21. As shown in FIG. 6, the plurality of openings 44 are formed between adjacent gas flow channels 42. The process gas may be supplied from three separate process gas supply sources 45-47 to the process gas supply port 43. The process gas supply sources 45-47 may supply H₂ gas, O₂ gas, and Ar gas. However, other gases may be used.

The process gas flows through the grid-like gas flow channels 42 and is uniformly supplied into the plasma diffusion region R2 via the plurality of gas supply holes 41. The plasma processing system 10 further includes four valves (V1-V4) and four mass flow rate controller (MFC1-MFC4) for controlling a supply of the process gas.

An external microwave generator 55 provides a microwave of a predetermined frequency, e.g., 2.45 GHz, to the antenna unit 50 via a coaxial waveguide 54. The coaxial waveguide 54 may include an inner conductor 54B and an outer conductor 54A. The microwave from the microwave generator 55 generates an electric field just below the plasma gas supply unit 30 in the plasma generation region R1, which in turn causes excitation of the process gas within the plasma processing chamber 20.

FIG. 7 illustrates a partial cross-sectional view of the antenna unit 50. As shown in this figure, the antenna unit 50 may include a flat antenna main body 51, a radial line slot plate 52, and a dielectric plate 53 to shorten the wavelength of the microwave. The flat antenna main body 51 can have a circular shape with an open-ended bottom surface. The flat antenna main body 51 and the radial line slot plate 52 can be made of a conductive material.

A plurality of slots 56 are provided on the radial line slot plate 52 to generate a circularly polarized wave. The plurality of slots 56 are arranged in a substantially T-shaped form with a small gap between each slot. The plurality of slots 56 are arranged in a concentric circle pattern or a spiral pattern along a circumferential direction. Since the slots 56a and 56b are perpendicular to each other, a circularly polarized wave containing two orthogonal polarized components is radiated, as a plane wave, from the radial line slot plate 52.

The dielectric plate 53 can be made of a low loss dielectric material, e.g., aluminum oxide (Al₂O₃) or silicon nitride (Si₃N₄), that is located between the radial line slot plate 52 and the flat antenna main body 51. The radial line slot plate 52 may be mounted on the plasma processing chamber 20 using sealing members (not shown), such that the radial line slot plate 52 is in close contact with a cover plate 23. The cover plate 23 is located on the upper surface of plasma gas supply unit 30 and is formed from a microwave transmissive dielectric material such as aluminum oxide (Al₂O₃).

An external high-frequency power supply source 22 is electrically connected to the substrate holder 21 via a matching network 25. The external high-frequency power supply source 22 generates an RF bias power of a predetermined frequency, e.g. 13.56 MHz, for controlling the energy of ions in the plasma that are drawn to the substrate W. The power supply source 22 is further configured to optionally provide pulsing of the RF bias power. The pulsing frequency can be greater than 1 Hz, for example 2 Hz, 4 Hz, 6 Hz, 8 Hz, 10 Hz, 20 Hz, 30 Hz, 50 Hz, or greater. The power supply source 22 is configured for supplying RF bias power between 0 W and 100 W, between 100 W and 200 W, between 200 W and 300 W, between 300 W and 400 W, or between 400 W and 500 W. One skilled in the art will appreciate that the power levels of the power supply source 22 are related to the size of the substrate being processed. For example, a 300 mm Si wafer requires greater power consumption than a 200 mm wafer during processing. The plasma processing system 10 further includes DC voltage generator 35 capable of supplying DC voltage bias between −5 kV and +5 kV to the substrate holder 21.

A germanium-containing semiconductor device and a method of forming have been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method for forming a germanium-containing semiconductor device, the method comprising:
providing a germanium-containing substrate;
depositing an aluminum-containing diffusion barrier layer on the germanium-containing substrate;
depositing a high-k layer on the aluminum-containing diffusion barrier layer; and
exposing the high-k layer to atomic oxygen to reduce the equivalent oxide thickness (EOT) of the high-k layer while avoiding oxidizing the germanium-containing substrate.

2. The method of claim 1, wherein the exposing includes exposing the high-k layer to plasma-excited oxidizing gas.

3. The method of claim 2, wherein the oxidizing gas consists of O₂ and optionally an inert gas.

4. The method of claim 1, wherein the germanium-containing substrate includes Ge or SiGe.

5. The method of claim 1, wherein the aluminum-containing diffusion barrier layer contains aluminum oxide, aluminum oxynitride, aluminum nitride, or a combination thereof.

6. The method of claim 1, wherein the high-k layer contains hafnium, zirconium, titanium, a rare earth element, or a combination thereof.

7. The method of claim 1, wherein the high-k layer contains an oxide of hafnium, an oxide of zirconium, an oxide of titanium, an oxide of a rare earth element, or a combination thereof.

8. The method of claim 1, wherein the EOT of the high-k layer is less than 0.7 nm following the exposing of the high-k layer to the atomic oxygen.

9. The method of claim 1, wherein a physical thickness of the aluminum-containing diffusion barrier layer is about lnm and a physical thickness of the high-k layer is about 3 nm.

10. The method of claim 1, wherein depositing the high-k layer comprises
forming at least one first monolayer of first material on a surface of the germanium-containing substrate by performing a first plurality of cycles of atomic layer deposition;
thereafter, annealing the formed at least one first monolayer of first material under a first inert atmosphere at a first temperature;
thereafter, forming at least one second monolayer of second material by performing a second plurality of cycles of atomic layer deposition, where the formed at least one second monolayer of second material at least partially overlies the annealed at least one first monolayer of first material; and
thereafter, annealing the formed at least one second monolayer of second material under a second inert atmosphere at a second temperature.

11. A germanium-containing semiconductor device comprising:
a germanium-containing substrate;
an aluminum-containing diffusion barrier layer on the germanium-containing substrate; and
a high-k layer on the aluminum-containing diffusion barrier layer, wherein the high-k layer has been exposed to atomic oxygen to reduce the equivalent oxide thickness (EOT) of the high-k layer while avoiding oxidizing the germanium-containing substrate.

12. The device of claim 11, wherein the atomic oxygen is generated by plasma-exciting an oxidizing gas.

13. The device of claim 12, wherein the oxidizing gas consists of O₂ and optionally an inert gas.

14. The device of claim 11, wherein the germanium-containing substrate includes Ge or SiGe.

15. The device of claim 11, wherein the aluminum-containing diffusion barrier layer contains aluminum oxide, aluminum oxynitride, aluminum nitride, or a combination thereof.

16. The device of claim 11, wherein the high-k layer contains hafnium, zirconium, titanium, a rare earth element, or a combination thereof.

17. The device of claim 11, wherein the high-k layer contains an oxide of hafnium, an oxide of zirconium, an oxide of titanium, an oxide of a rare earth element, or a combination thereof.

18. The device of claim 11, wherein the EOT of the high-k layer is less than 0.7 nm following the atomic oxygen exposure.

19. The device of claim 11, wherein a physical thickness of the aluminum-containing diffusion barrier layer is about 1 nm and a physical thickness of the high-k layer is about 3 nm.

20. The device of claim 11, wherein the high-k layer is deposited by
forming at least one first monolayer of first material on a surface of the germanium-containing substrate by performing a first plurality of cycles of atomic layer deposition;
thereafter, annealing the formed at least one first monolayer of first material under a first inert atmosphere at a first temperature;
thereafter, forming at least one second monolayer of second material by performing a second plurality of cycles of atomic layer deposition, where the formed at least one second monolayer of second material at least partially overlies the annealed at least one first monolayer of first material; and
thereafter, annealing the formed at least one second monolayer of second material under a second inert atmosphere at a second temperature.
